(19) United States
(12) Patent Application Publication
(10) Pub. No.: US 2011/0247557 A1
(43) Pub. Date: Oct. 13, 2011

(54) DEVICE FOR SEALING A CHAMBER INLET OR A CHAMBER OUTLET FOR A FLEXIBLE SUBSTRATE, SUBSTRATE PROCESSING APPARATUS, AND METHOD FOR ASSEMBLING SUCH A DEVICE

(75) Inventors: Karl-Heinrich WENK, Bad Nauheim (DE); Volker HACKER, Altenstadt-Oberau (DE)

(73) Assignee: APPLIED MATERIALS, INC., Santa Clara, CA (US)

(21) Appl. No.: 12/759,246

(22) Filed: Apr. 13, 2010

(30) Foreign Application Priority Data
Apr. 7, 2010 (EP) 10159259

(51) Int. Cl. C23C 16/00; F16J 15/16; B23P 11/00

(52) U.S. Cl. 118/715; 29/428; 277/345

(57) ABSTRACT

The present disclosure relates to a device for sealing a chamber inlet or a chamber outlet for a flexible substrate, comprising a body having a sealing surface, a substrate opening formed in the body configured to be traversed by the flexible substrate, an elastic tube at least partially facing the sealing surface, wherein the elastic tube has a connecting portion for connecting to a gas supply and being adapted for inflating and deflating during operation. Further, the present disclosure relates to a substrate processing apparatus for processing a flexible substrate, the substrate processing apparatus comprising a first chamber and a second chamber separated from the first chamber, and a device for sealing a chamber inlet or a chamber outlet for a flexible substrate, the device comprising a body having a sealing surface, a substrate opening formed in the body configured to be traversed by the flexible substrate, an elastic tube at least partially facing the sealing surface, wherein the elastic tube has a connecting portion for connecting to a gas supply and being adapted for inflating and deflating during operation, wherein the device selectively opens or closes a fluid connection between the first and the second chamber. Additionally, the present disclosure relates to a method for assembling a device for sealing a chamber inlet or a chamber outlet for a flexible substrate, comprising providing a body having a sealing surface, wherein a substrate opening is formed in the body configured to be traversed by the flexible substrate; inserting an elastic tube into the body, such that the elastic tube is facing at least partially the sealing surface, the elastic tube having a connecting portion and being adapted for inflating and deflating during operation; and connecting the connecting portion of the elastic tube to a gas supply.

The present disclosure relates to a device for sealing a chamber inlet or a chamber outlet for a flexible substrate. In particular, the present disclosure relates to a device having a body and a substrate opening formed in the body.

Further, the present disclosure relates to a substrate processing apparatus for processing a flexible substrate, the substrate processing apparatus including a first chamber and a second chamber separated from the first chamber.

Additionally, the present disclosure relates to a method for assembling a device for sealing a chamber inlet or a chamber outlet for a flexible substrate.

### BACKGROUND

In many applications, it is necessary to deposit thin layers on a flexible substrate.

Typically, the flexible substrates are coated in different chambers of a flexible substrate coating apparatus. Further, a stock of a flexible substrate, for example, a roll of a flexible substrate, may be disposed in one chamber of the substrate coating apparatus. Typically, the flexible substrates are coated in a vacuum, using a vapour deposition technique, for example, physical vapour deposition or chemical vapour deposition. However, for repairing or exchanging some devices in the chambers, or for refilling or restocking the stock of flexible substrate, at least one of the chambers may be pressurised to atmosphere pressure, such that a person may access the chamber or the stock of flexible substrate may be refilled or retrieved. In other examples, the stock of flexible substrate may remain in vacuum when a deposition apparatus has to be serviced, for example, a target of a sputtering apparatus needs to be changed. However, other chambers of the substrate coating apparatus may still remain evacuated. For these purposes, a chamber may be sealed from another chamber, in particular when the flexible substrate is traversing a wall between two chambers.

Thus, it is possible that one chamber has a very low pressure, while the other chamber has a relative high pressure, even when the flexible substrate is traversing the wall between the two chambers.

### SUMMARY

In light of the above, a device for sealing a chamber inlet or a chamber outlet for a flexible substrate is provided, including a body having a sealing surface, a substrate opening formed in the body configured to be traversed by the flexible substrate, an elastic tube at least partially facing the sealing surface, wherein the elastic tube has a connecting portion for connecting a gas supply and being adapted for inflating and deflating during operation.

According to a further aspect, a substrate processing apparatus for processing a flexible substrate is provided, the substrate processing apparatus comprising a first chamber and a second chamber separated from the first chamber, and a device for sealing a chamber inlet or a chamber outlet for a flexible substrate, the device comprising a body having a sealing surface, a substrate opening formed in the body configured to be traversed by the flexible substrate, an elastic tube at least partially facing the sealing surface, wherein the elastic tube has a connecting portion for connecting to a gas supply and being adapted for inflating and deflating during operation, wherein the device selectively opens or closes a fluid connection between the first and the second chamber.

According to a further aspect, a method for assembling a device for sealing a chamber inlet or a chamber outlet for a flexible substrate is provided, including: providing a body having a sealing surface, wherein a substrate opening is formed in the body configured to be traversed by the flexible substrate; inserting an elastic tube into the body, such that the elastic tube is at least partially facing the sealing surface, the elastic tube having a connecting portion and being adapted for inflating and deflating during operation; and connecting the connecting portion of the elastic tube to a gas supply.

### BRIEF DESCRIPTION OF THE DRAWINGS

A full and enabling disclosure including the best mode thereof, to one of ordinary skill in the art, is set forth more particularly in the remainder of the specification, including reference to the accompanying figures wherein:

FIG. 1 shows schematically a sectional view of a wall including a device for sealing a chamber inlet or chamber outlet;

FIG. 2 shows schematically a traversal cross section B-B of FIG. 3 of a device for sealing a chamber inlet or chamber outlet;

FIG. 3 shows schematically a longitudinal cross section A-A of FIG. 2 of a device for sealing a chamber inlet or chamber outlet; and

FIG. 4 shows a flowchart of a method for assembling a device for sealing a chamber inlet or a chamber outlet.

### DETAILED DESCRIPTION OF THE EMBODIMENTS

Reference will now be made in detail to the various embodiments, one or more examples of which are illustrated in the figures. Each example is provided by way of explanation, and is not meant as a limitation of the invention. Within the following description of the drawings, the same reference numbers refer to the same components. Generally, only the differences with respect to the individual embodiments are described.

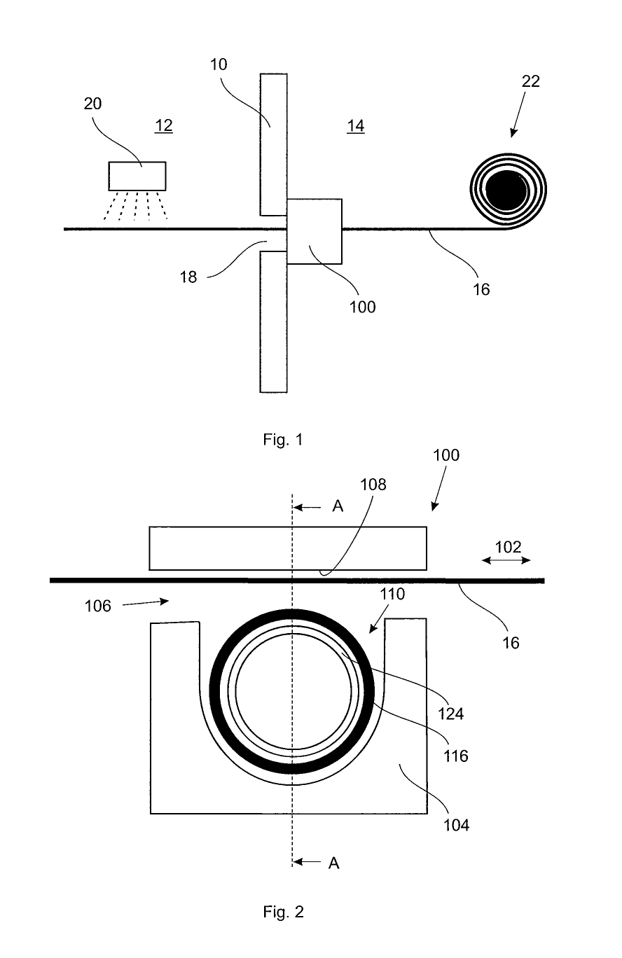

FIG. 1 shows schematically a side view of a cross section of a wall 10 between a first chamber 12 and a second chamber 14. In both chambers 12, 14, a flexible substrate 16 is processed. Typically, during processing, the chambers 12, 14 have a pressure of about 10⁻⁴ mbar or about 10⁻⁵ mbar. For example, in first chamber 12 the flexible substrate 16 may be coated by a coating device 20. In chamber 14, the flexible substrate may be rolled up or unrolled on a flexible substrate roll 22. Typically, the flexible substrate 16 traverses the wall 10 through a wall opening 18. The first chamber 12 and a second chamber 14 may have different pressures, for example, when the roll 22 is exchanged with a new roll 22. Then, the wall opening 18 may be sealed tightly, even if a portion of the flexible substrate 16 is traversing the wall opening 18.

For this purpose, a device for sealing a chamber inlet or chamber outlet 100 is disposed at or in the wall opening 18. The device 100 is traversed by the flexible substrate 16. In further embodiments, which may be combined with other embodiments disclosed herein, the device 100 may be integrated in the wall 10 or be a portion of the wall 10, so that the wall opening may correspond to a substrate opening of the device 100. In some embodiments, the device 100 is tightly fixed to the wall 10, for example, by screws or bolts.

FIG. 2 shows schematically a traversal cross section of the device 100. The device 100 includes a body 104 having a substrate opening 106 which is typically traversed by the flexible substrate 16 in a transport direction 102 of the flexible substrate. In a typical embodiment, which may be combined with other embodiments disclosed herein the body 104 is manufactured from a rigid material, typically a metal, e.g., steel or stainless steel. For example, in an embodiment, the body 104 may be manufactured from subassemblies, the subassemblies may then correspond respectively to a half of the body 104.

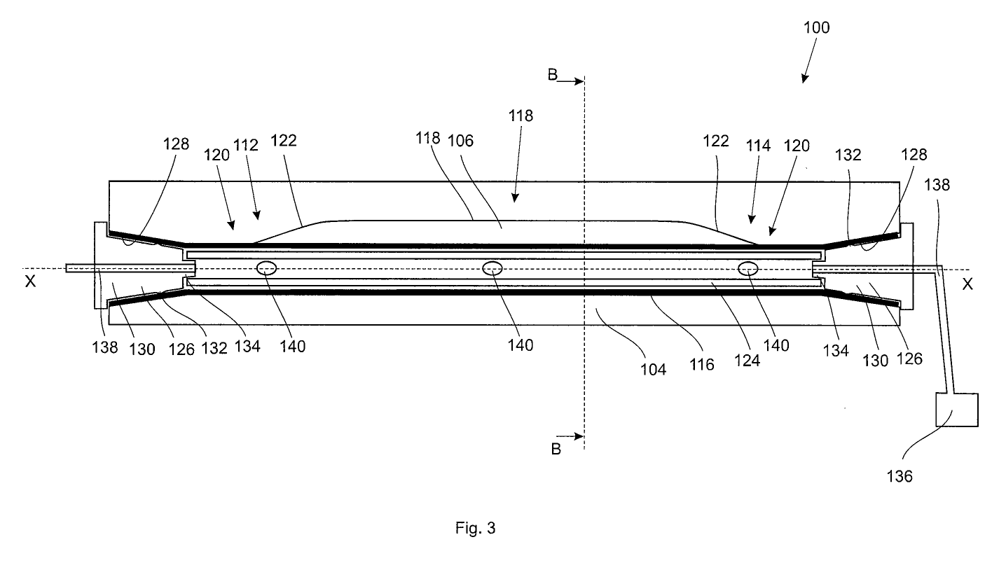

The substrate opening 106 has sealing surface 108, typically extending along the longitudinal direction of the device 100, and opposite to the sealing surface 108, a groove or a recess 110 is disposed. As can be seen in the longitudinal cross section of the device 100 shown in FIG. 3, the substrate opening 106 has a first end 112 and a second end 114 in the longitudinal direction X of the device 100. In FIG. 3, the device 100 is shown without a traversing flexible substrate.

In the recess 110, an elastic tube 116 is arranged. In a typical embodiment, the elastic tube 116 may be manufactured, from rubber, viton, silicone, and/or nitrile butadiene rubber (NBR). The elastic tube may be inflated, such that, in an embodiment, a portion of the surface of the elastic tube 116 is pressed against the sealing surface 108. In case the flexible substrate 16 is traversing the substrate opening 106, the inflated elastic tube is pressed against the flexible substrate 16.

Typically, the deflated elastic tube may have an outer diameter between about 25 mm and about 50 mm, in particular, between 30 mm and 45 mm. Further, the deflated elastic tube may have a thickness between 2 mm and about 8 mm, in particular between about 3 mm and about 7 mm.

In an embodiment, the elastic tube 116 exceeds the substrate opening 106 in longitudinal direction X. Thus, the longitudinal extension of elastic tube 116 is greater than the longitudinal extension of the substrate opening 106. In a typical embodiment, which may be combined with other embodiments disclosed herein, the elastic tube 116 may be inflated by a pressure source.

The sealing surface typically has a longitudinal axis substantially parallel to a longitudinal axis X of the device 100, which may coincide in an embodiment, which may be combined with other embodiments disclosed herein, with a longitudinal axis X of the elastic tube 116.

Typically, the recess 110 is substantially U-shaped in a traversal cross-section, such that the inflated elastic tube 116 may press tightly against the wall of the recess 110. In another embodiment, the recess 110 may be substantially half-circular or half-oval shaped in a traversal cross-section. In a typical embodiment, the traversal extension of the recess 110 corresponds substantially to the outer diameter of the deflated elastic tube 116. For example, the radius of the half-circular portion of the U-shaped cross section may have a radius corresponding to, or slightly exceeding, the external radius of the deflated elastic tube. For example, the radius of the half circular portion of the recess may exceed 5% of the outer radius of the deflated elastic tube. In another embodiment, the deflated elastic tube may be in contact with the wall of the recess. In an embodiment, which may be combined with other embodiments disclosed herein, the radius of the half circular portion of the recess may be between about 15 mm and about 30 mm, in particular about 20 mm.

Typically, a contiguous portion of the inflated elastic tube 116, the contiguous portion being in particular disposed along the longitudinal axis X, is pressed against the wall of the recess. Typically, the contiguous portion extends at least between the first end 112 and the second end 114 of the substrate opening 106. Thus, in case of an inflated elastic tube fluid communication between the first chamber 12 and the second chamber 14 passing through the recess is substantially prevented, even in the case of large pressure differences.

In a typical embodiment, which may be combined with other embodiments, a rigid tube 124 is disposed within the elastic tube 116, the rigid tube 124 having, in a typical embodiment, at least the length of the substrate opening 106. In a typical embodiment, the rigid tube 124 may have a length in longitudinal axis X of the device 100 exceeding the longitudinal extension of the substrate opening 106. Further, in an embodiment, the longitudinal extension of elastic tube 116 is greater than the longitudinal extension of the rigid tube 124. For example, in an embodiment, which may be combined with other embodiments disclosed herein, the rigid tube may have an outer diameter being slightly smaller, for example 5% to 20% smaller, than the inner diameter of the deflated elastic tube. Hence, a space is formed between the deflated elastic tube and the rigid tube.

In some embodiments, a rigid bar, in particular a cylindrical rigid bar, may be disposed in the elastic tube 116. The rigid bar may be used in some embodiments instead of the rigid tube. Typically, the rigid tube may be an embodiment of the rigid bar. The rigid bar may have, in a typical embodiment, at least the length of the substrate opening 106. In a typical embodiment, the rigid bar may have a length in longitudinal axis X of the device exceeding the longitudinal extension of the substrate opening 106. In a typical embodiment, the longitudinal extension of elastic tube 116 is greater than the longitudinal extension of the rigid bar. For example, in an embodiment, which may be combined with other embodiments disclosed herein, the rigid bar may have an outer diameter being slightly smaller, for example 5% to 20% smaller, than the inner diameter of the deflated elastic tube. Hence, a space is formed between deflated elastic tube and the rigid bar. Typically, the rigid bar is more rigid than the elastic tube. For example, the rigid bar may be fabricated of a metal, for example steel.

In an embodiment, the rigid tube 124 and/or the rigid bar is maintained in a fixed position in the recess 110 of the device 100. Hence, the elastic tube 116 is maintained by the rigid tube or the rigid bar in a fixed position in the device 100. Thus, even in a deflated state, the elastic tube retracts into or in the direction of the recess, such that the deflated elastic tube 116 may not harm a flexible substrate 116 traversing the substrate opening 106. Thus, the deflated elastic tube 116 may not scratch the flexible substrate.

Typically, the rigid tube 124 or the rigid bar are more rigid than the elastic tube 116, in particular as they are adapted to maintain the deflated elastic tube in the recess. For example, the rigid tube may be fabricated of a metal, e.g. aluminium, stainless steel, or steel.

In a typical embodiment, which may be combined with other embodiments disclosed herein, the recess 110 is extended at each extremity 112, 114 of the opening in the direction of the longitudinal axis X by a tube mounting opening 126. The tube mounting opening 126 is used to insert the elastic tube 116 and the rigid tube 124 into the recess 110. Typically, the tube mounting openings 126 have respectively a lateral portion with a substantially conical surface 128. In a typical embodiment, which may be combined with other embodiments, the elastic tube is pressed by a plug 130 against the conical surface 128 of the tube mounting opening 126. In a typical embodiment, the plug 130 may have a circumferential protrusion 132, such that a fluid flow in the longitudinal direction of the recess through the tube mounting opening 126 is prevented. Further, the plug 130 may have, in an embodiment, a support protrusion 134 for supporting the rigid tube 124. Thus, the rigid tube 124 is fixed in its position in the recess 110. Typically, the plugs 130 are fixed, for example by a screw or a bolt, to the body 104 of the device 100.

The plug is further designed to provide a fluid connection 138 between a fluid supply 136 and an interior of the elastic tube 116. For example, each plug may have such a fluid connection 138. In a further embodiment, a first plug may be connected with a pump for evacuating or deflating the elastic tube, and the other fluid connection 138 may be connected with a pressure source 136. In a typical embodiment, which may be combined with other embodiments disclosed herein, the fluid supply is connected to the interior of the rigid tube 124. For providing the pressure to the space between the rigid tube and elastic tube 116, the rigid tube may include openings 140 such that a fluid connection is possible between the interior of the rigid tube 124 and the space between the rigid tube 124 and the elastic tube 116. For example, elastic tube 116 may be inflated such that the interior of the inflated elastic tube 116 has a pressure of about 6 bar.

In some embodiments, the fluid connection 138 may be disposed, so that the compressed air is directly provided in the space between the rigid tube 124 and the elastic tube 116.

As the elastic tube 116 is mechanically and tightly pressed against the sealing surface of the tube mounting opening 126, the elastic tube 116 is typically not vulcanized or galvanized to the body 104. Hence, the elastic tube 116 is easily replaceable in the device 100.

In a typical embodiment, the sealing surface includes a central portion 118. In a typical embodiment, a lateral portion 120 is respectively disposed at each longitudinal extremity of the sealing surface 108. In some embodiments, the lateral portions 120 may be disposed, at least partially, in the tube mounting opening 126.

Further, the sealing surface 108 may include an intermediate portion 122 between each lateral portion and the central portion 118. Typically, the lateral portions 120 are disposed at a first end 112 and a second end 114 of the sealing surface 108. In a typical embodiment, the central portion and/or the lateral portions 120 is/are substantially parallel to the longitudinal axis X of the elastic tube 116 or the device 110.

Typically, there is a smooth transition between the central portion and the intermediate portions and between the intermediate portions and the respective lateral portions. For example, the radius of the cavity of the transitions between the lateral portion and the respective adjacent intermediate portions, or the intermediate portions and the central portion, may be greater than 80 mm, in particular greater than 90 mm. For example, the radius of curvature may be between 90 mm and 120 mm.

Further, circular segments of the transitions between the portions of the sealing surface may be smaller than 15 degrees, in particular less than 10 degrees. For example, the angle of the transition between the portions of the sealing surface may be between 5 degrees and 10 degrees.

Thus, even if the elastic tube is pressurized and presses the substrate against the sealing surface 108, a tight connection may be realized.

A device according to embodiments disclosed herein is extremely tight, such that a reliable separation of chambers having a different air pressure may be realized, even if a flexible substrate is present within the substrate opening. In particular, the robust and round tube design enables a high level of tightness.

Thus, in the case of an inflated elastic tube fluid communication between a first chamber and the second chamber is substantially prevented, even in the case of large pressure differences between the first chamber and the second chamber. For example, a chamber may be an unwind or rolling up chamber of a flexible substrate processing device, wherein the unwind or rolling up chamber is adjacent to a deposition chamber. According to an embodiment, the unwind or rolling up chamber may be sealed vacuum tight against the deposition chamber. Thus, for example, a target of a physical vapour deposition apparatus may be changed without exposing the flexible substrate in another chamber to the atmosphere, which may contain small particles.

Thus, the device 100 seals vacuum tight an opening between a first chamber and a second chamber, even if the flexible substrate is traversing the device 100. Typically, the flexible substrate does not harm the tightness of the device, even if it is present in the substrate opening. According to the embodiments disclosed, an elastic tube is disposed in a recess and may be pressurized with pressurized air, such that it is inflated and closes the opening for the flexible substrate. The elastic tube may only extend substantially in the direction of the sealing surface, so that the substrate is pressed against the facing sealing surface. In the open state, the elastic tube retracts into the recess and clears the substrate opening.

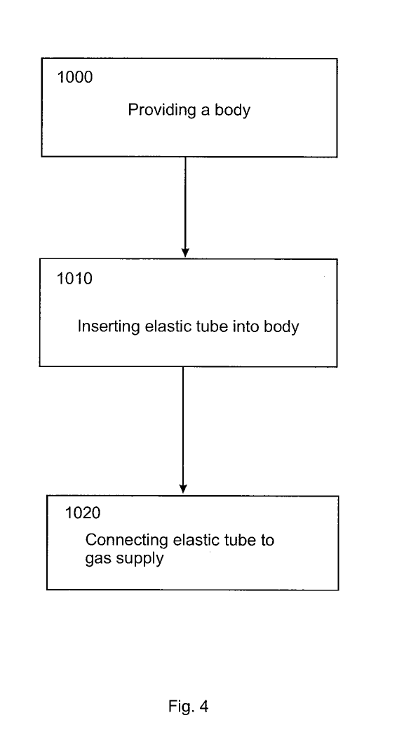

FIG. 4 shows a schematic drawing of a method for assembling a device for sealing a chamber inlet or a chamber outlet for a flexible substrate. In box 1000, a body is provided. The body has a sealing surface, and a substrate opening is formed in the body configured to be traversed by the flexible substrate. In a typical embodiment, a recess is formed in the body opposite the sealing surface. In box 1010, an elastic tube is inserted into the body, for example, in the recess of the body, such that the elastic tube is partially facing the sealing surface. For example, the elastic tube may be provided through a tube mounting opening provided in the body. In a further embodiment, a rigid tube may be provided in the elastic tube. Typically, in box 1020, the elastic tube, in particular the interior of the elastic tube, is connected to a gas supply, for example a pressurized air source. Thus, the elastic tube may be inflated for closing the substrate opening.

In a typical embodiment, the recess is substantially without corners. For example, a contiguous portion of the elastic tube, in particular extending between a first end of the substrate opening to a second end of the substrate opening, is pressed against the wall of the recess.

In a typical embodiment, which may be combined with other embodiments disclosed herein, the device further includes a recess formed in the body opposite to the sealing surface, wherein in particular the recess is substantially U-shaped or has a substantial semi-circular cross-section in a section orthogonal to a longitudinal axis of the elastic tube.

In a typical embodiment, which may be combined with other embodiments disclosed herein, the recess has in particular the form of a groove.

For example, in an embodiment, the recess has a longitudinal axis substantially parallel to the longitudinal axis of the elastic tube.

In a typical embodiment, which may be combined with other embodiments disclosed herein, the elastic tube is arranged at least partially in the recess.

For example, in an embodiment, the sealing surface is formed in the substrate opening.

In a typical embodiment, which may be combined with other embodiments disclosed herein, the longitudinal axis of the elastic tube is substantially orthogonal to the transport direction of the flexible substrate.

In a typical embodiment, which may be combined with other embodiments disclosed herein, a rigid bar, in particular a rigid tube, is disposed within the elastic tube, wherein in particular the interior of the rigid tube is in fluid connection with a space between the rigid tube and the elastic tube. In a typical embodiment, the rigid bar may be fabricated of a metal, for example, steel. In a typical embodiment, the rigid bar is in the form of a rigid tube.

For example, in an embodiment, the body includes at least one tube mounting opening extending the recess in direction of the longitudinal axis of the recess for mounting at least one element selected of the group consisting of the elastic tube and the rigid bar.

In a typical embodiment, which may be combined with other embodiments disclosed herein, the at least one tube mounting opening has a circumferential tube mounting opening sealing surface, wherein the elastic tube is pressed against the tube mounting opening sealing surface, such that a fluid flow in the direction through the at least one tube mounting opening is prevented, wherein in particular the supply opening sealing surface is substantially conical.

In a typical embodiment, which may be combined with other embodiments disclosed herein, the device further includes at least one plug disposed respectively in a tube mounting opening, wherein the plug presses the elastic tube against the mounting opening sealing surface, wherein in particular the at least one plug is substantially conical.

In a typical embodiment, the plug is adapted to the mounting opening sealing surface.

For example, in an embodiment, the at least one plug maintains the rigid bar, in particular the rigid tube.

In a typical embodiment, which may be combined with other embodiments disclosed herein, the at least one plug includes a fluid channel for connecting the interior of the elastic tube to at least one source selected of a group consisting of a pressure source and a vacuum source.

For example, in an embodiment, when in an inflated state, a portion of the elastic tube is pressed against the surface of the recess facing the substrate opening sealing surface.

In a typical embodiment, which may be combined with other embodiments disclosed herein, the device is provided in a wall between the first chamber and the second chamber.

According to a further aspect, the device further includes a recess formed in the body opposite to the sealing surface, wherein the method includes inserting the elastic tube at least partially into the recess.

For example, in an embodiment, the body includes at least one tube supply opening extending the recess in the direction of its longitudinal axis, wherein the elastic tube is introduced into the recess through the tube supply opening.

In an embodiment, which may be combined with other embodiments disclosed herein, the method further includes: pressing the elastic tube against a circumferential tube supply opening sealing surface of the at least one tube supply opening, such that a fluid flow in the direction through the at least one tube supply opening is prevented.

In a typical embodiment, which may be combined with other embodiments disclosed herein, the method may include: arranging the elastic tube around a rigid bar, wherein in particular the rigid bar is in the form of a rigid tube.

In a typical embodiment, which may be combined with other embodiments disclosed herein, the sealing surface has a longitudinal axis and includes a central portion, in particular substantially parallel to the elastic tube or the longitudinal axis of the elastic tube. Further, the sealing surface may include a lateral portion at each longitudinal extremity of the sealing surface, and an intermediate portion between each lateral portion and the central portion, wherein in particular the elastic tube is permanently pressed against the lateral portions, in particular when the elastic tube is inflated or deflated.

For example, in an embodiment, the radius of curvature of the transition between the lateral portions and the respective adjacent intermediate portions is greater than 80 mm, in particular greater than 90 mm. For example, the radius of curvature may be between 90 mm and 120 mm.

In a typical embodiment, which may be combined with other embodiments disclosed herein, the radius of curvature of the transition between the central portion and the intermediate portions is respectively greater than 80 mm, in particular greater than 90 mm. For example, the radius of curvature may be between 90 mm and 120 mm.

For example, in an embodiment, the angle of a circular segment of the transition between the central portion and the intermediate portion is respectively smaller than 15 degrees, in particular less than 10 degrees. For example, the angle of the transition between the central portion and the intermediate portion is between 5 degrees and 10 degrees.

In a typical embodiment, which may be combined with other embodiments disclosed herein, the angle of a circular segment of the transition between the lateral portion and the respective adjacent intermediate portions is smaller than 15 degrees, in particular less than 10 degrees. For example, the angle of the transition between the lateral portion and the respective adjacent intermediate portion is between 5 degrees and 10 degrees.

For example, in an embodiment, the intermediate portions are between 5 percent and 15 percent of the extension of the opening in longitudinal extension of the sealing surface.

This written description uses examples to disclose the invention, including the best mode, and also to enable any person skilled in the art to practice the described subject-matter, including making and using any devices or systems and performing any incorporated methods. While various specific embodiments have been disclosed in the foregoing, those skilled in the art will recognize that the spirit and scope of the claims allows for equally effective modifications. Especially, mutually non-exclusive features of the embodiments described above may be combined with each other. The patentable scope is defined by the claims, and may include such modifications and other examples that occur to those skilled in the art. Such other examples are intended to be within the scope of the claims if they have structural elements that do not differ from the literal language of the claims, or if they include equivalent structural elements with insubstantial differences from the literal language of the claims.

1. A device for sealing a chamber inlet or a chamber outlet for a flexible substrate, comprising
a body having a sealing surface,
substrate opening formed in the body configured to be traversed by the flexible substrate,
an elastic tube at least partially facing the sealing surface, wherein the elastic tube has a connecting portion for connecting a gas supply and being adapted for inflating and deflating during operation.

2. The device according to claim 1, further comprising
a recess formed in the body opposite to the sealing surface.

3. The device according to claim 2, wherein
the recess has a longitudinal axis substantially parallel to the longitudinal axis of the elastic tube.

4. The device according to claim 2, wherein
the elastic tube is arranged at least partially in the recess.

5. The device according to claim 1, wherein
the sealing surface is formed in the substrate opening.

6. The device according to claim 1, wherein
a rigid bar is disposed within the elastic tube.

7. The device according to claim 2, wherein the body comprises at least one tube mounting opening extending the recess in the direction of the longitudinal axis of the recess for mounting at least one element selected of the group consisting of the elastic tube and the rigid bar.

8. The device according to claim 7, wherein the at least one tube mounting opening has a circumferential tube mounting opening sealing surface, wherein the elastic tube is pressed against the tube mounting opening sealing surface, such that a fluid flow in direction through the at least one tube mounting opening is prevented.

9. The device according to claim 8, further comprising
at least one plug disposed respectively in a tube mounting opening, wherein the plug presses the elastic tube against the mounting opening sealing surface.

10. The device according to claim 9, wherein
the at least one plug maintains the rigid bar.

11. The device according to claim 9, wherein
the at least one plug comprises a fluid channel for connecting the interior of the elastic tube to at least one of sources selected of a group consisting of a pressure source and a vacuum source.

12. The device according to claim 2, wherein
in an inflated state, a portion of the elastic tube is pressed against the surface of the recess facing the substrate opening sealing surface.

13. A substrate processing apparatus for processing a flexible substrate, the
substrate processing apparatus comprising
a first chamber and a second chamber separated from the first chamber, and a device for sealing a chamber inlet or a chamber outlet for a flexible substrate, the device comprising
a body having a sealing surface,
a substrate opening formed in the body configured to be traversed by the flexible substrate,
an elastic tube at least partially facing the sealing surface, wherein
the elastic tube has a connecting portion for connecting to a gas supply and being adapted for inflating and deflating during operation, wherein the device selectively opens or closes a fluid connection between the first and the second chamber.

14. The substrate processing apparatus according to claim 13, wherein the device further comprises a recess formed in the body opposite to the sealing surface.

15. The substrate processing apparatus according to claim 14, wherein the elastic tube is arranged at least partially in the recess.

16. The substrate processing apparatus according to claim 13, wherein the sealing surface is formed in the substrate opening.

17. The substrate processing apparatus according to claim 13, wherein a rigid bar is disposed within the elastic tube.

18. The substrate processing apparatus according to claim 14, wherein the body comprises at least one tube mounting opening extending the recess in the direction of the longitudinal axis of the recess for mounting at least one element selected of the group consisting of the elastic tube and the rigid bar.

19. The substrate processing apparatus according to claim 18, wherein the at least one tube mounting opening has a circumferential tube mounting opening sealing surface, wherein the elastic tube is pressed against the tube mounting opening sealing surface, such that a fluid flow in direction through the at least one tube mounting opening is prevented.

20. The substrate processing apparatus according to claim 13, wherein the device is provided in a wall between the first chamber and the second chamber.

21. A method for assembling a device for sealing a chamber inlet or a chamber outlet for a flexible substrate, comprising
providing a body having a sealing surface, wherein a substrate opening is formed in the body configured to be traversed by the flexible substrate;
inserting an elastic tube into the body, such that the elastic tube is facing at least partially the sealing surface, the elastic tube having a connecting portion and being adapted for inflating and deflating during operation; and
connecting the connecting portion of the elastic tube to a gas supply.

22. The method according to claim 21, wherein
the device is further comprising a recess formed in the body opposite to the sealing surface, wherein the method comprises
inserting the elastic tube at least partially into the recess.

23. The method according to claim 22, wherein
the body comprises at least one tube supply opening extending the recess in direction of its longitudinal axis, wherein the elastic tube is introduced in the recess through the tube supply opening.

24. The method according to claim 23, further comprising
pressing the elastic tube against a circumferential tube supply opening sealing surface of the at least one tube supply opening, such that a fluid flow in direction through the at least one tube supply opening is prevented.

25. The method according to claim 21, further comprising
arranging the elastic tube around a rigid bar.
